(19) United States
(12) Patent Application Publication
(10) Pub. No.: US 2025/0389797 A1
(43) Pub. Date: Dec. 25, 2025

(54) MEMORY-EFFICIENT MONITORING OF A MAGNETIC RESONANCE SCAN USING A PREFIX-FREE CODE

(71) Applicant: Siemens Healthineers AG, Forchheim (DE)

(72) Inventor: Rene Gumbrecht, Bamberg (DE)

(21) Appl. No.: 19/243,154

(22) Filed: Jun. 19, 2025

(30) Foreign Application Priority Data
Jun. 19, 2024 (DE) 10 2024 205 653.7

(51) Int. Cl. G01R 33/28; G01R 33/54

(52) U.S. Cl. CPC G01R 33/288; G01R 33/543

(57) ABSTRACT

A method for monitoring a magnetic resonance scan, a magnetic resonance apparatus, and a computer program product are provided. Herein, monitoring measured values are captured during the magnetic resonance scan. Monitoring memory values are generated by quantizing the monitoring measured values. The monitoring memory values are stored as prefix-free code in a memory unit. The stored monitoring measured values are used to monitor the magnetic resonance scan for compliance with a monitoring limit value.

This application claims the benefit of German Patent Application No. DE 10 2024 205 653.7, filed on Jun. 19, 2024, which is hereby incorporated by reference in its entirety.

### BACKGROUND

The present embodiments relate to a method for monitoring a magnetic resonance scan, a magnetic resonance apparatus, and a computer program product.

In medical technology, high soft-tissue contrast is a characteristic feature of magnetic resonance imaging (MRI). A magnetic resonance scan is performed by a magnetic resonance apparatus. Herein, a main magnet of the magnetic resonance apparatus may generate a main magnetic field, and a gradient coil unit generates a gradient magnetic field in an examination region of the magnetic resonance apparatus. A patient is located in the examination region during a magnetic resonance scan. Herein, to generate magnetic resonance signals, radiofrequency (RF) pulses are irradiated into the examination region in accordance with a magnetic resonance sequence. The magnetic resonance signals are received as measurement data by the magnetic resonance apparatus and used for the reconstruction of magnetic resonance images. The magnetic resonance signals may be received using MR local coils (e.g., receiving coils arranged locally on the patient in order to achieve a high signal-to-noise ratio).

The irradiation of RF pulses delivers thermal energy to the patient, causing the patient's body to heat up. In the case of magnetic resonance apparatuses with a single transmit channel, RF heating (e.g., the specific absorption rate (SAR)) is proportional to the RF power applied to the patient. Regulatory standards require the average SAR value to be limited to a specific value over specific time intervals. Typically, in each case, a SAR limit value is defined for a 10-second and a 6-minute average. These limits apply to each 10-second or 6-minute interval and therefore require a moving average calculation to obtain the average SAR value. For example, for a 6-minute interval, the SAR value is stored every 100 ms, and 3600 values are added to obtain the moving average. This may require approximately 15 kB memory space (e.g., RAM).

However, in the case of MRI systems with a plurality of transmit channels (e.g., with 8 or more transmit channels), the moving average is to be calculated not only for a single variable, but for a large number of variables. This often requires a significantly larger memory space (e.g., 15 MB or more). Since SAR monitoring algorithms may be implemented on small embedded systems, this amount of memory is often not available.

### SUMMARY AND DESCRIPTION

The scope of the present invention is defined solely by the appended claims and is not affected to any degree by the statements within this summary.

The present embodiments may obviate one or more of the drawbacks or limitations in the related art. For example, a memory-efficient method for monitoring a magnetic resonance scan is provided.

Accordingly, a computer-implemented method for monitoring a magnetic resonance scan is provided. Herein, monitoring measured values captured during the magnetic resonance scan are provided. For example, the method may also include capturing the monitoring measured values during the magnetic resonance scan. Monitoring memory values are generated by quantizing the monitoring measured values. The monitoring memory values are stored as prefix-free code (e.g., of variable length) in a memory unit. The stored monitoring measured values are used to monitor the magnetic resonance scan for compliance with a (specified) monitoring limit value.

The monitoring limit value may, for example, be read from a database and/or ascertained (e.g., calculated) before monitoring begins. In one embodiment, the monitoring limit value is set to provide that regulatory standards are complied with.

In one embodiment, the magnetic resonance scan is monitored for compliance with further limit values (e.g., in addition to the monitoring limit value). If a plurality of limit values is monitored during monitoring, the monitoring limit value may be the limit value that monitoring requires the most memory space of the memory unit.

If, for example, the monitoring of the magnetic resonance scan provides for monitoring SAR exposure in a (e.g., rolling) 10-second time window and also monitoring of SAR exposure in a (e.g., rolling) 6-minute time window, the monitoring of the limit value for the 6-minute time window (e.g., with otherwise identical conditions, such as the time resolution of the monitoring) requires a larger memory of space of the memory unit due to the larger amount of monitoring memory values to be stored.

In one embodiment, when monitoring a plurality of limit values, the method of the present embodiments is executed a number of (e.g., several) times in parallel (e.g., with a separate memory unit in each case).

For example, the monitoring measured values are (e.g., temporally) sequentially captured monitoring measured values. For example, the monitoring measured values are (e.g., temporally) consecutive monitoring measured values. For example, the monitoring measured values are captured at constant time intervals. For example, the monitoring measured values may be captured in time intervals of 100 ms (e.g., in this case, the time resolution of the monitoring would be 100 ms).

In one embodiment, the monitoring measured values characterize a variable to be monitored. In one embodiment, the monitoring measured values are suitable for deriving therefrom at least one value (e.g., a SAR value) that may be compared with the monitoring limit value. The monitoring measured value may, for example, be a power (e.g., an RF power) and/or a voltage of a transmit channel of the magnetic resonance apparatus. The monitoring limit value may, for example, include a SAR limit value or be a SAR limit value. Accordingly, the monitoring measured values and monitoring memory values derived therefrom may represent SAR values.

Quantizing the monitoring measured values may, for example, include discretizing the monitoring measured values. The monitoring measured values are, for example, continuous and/or constant values. For example, each monitoring measured value is in each case assigned a discrete monitoring memory value. For example, each monitoring measured value is in each case transferred to a discrete monitoring memory value and/or mapped to a discrete monitoring memory value.

In one embodiment, the quantization of the monitoring measured values takes place in N quantization levels, where N is ≤500 (e.g., ≤200). In one embodiment, N is selected as low as possible in order to save memory space. In one embodiment, N is selected as high as necessary in order to enable sufficiently accurate evaluation of the monitoring measured values (e.g., in order enable a patient's SAR exposure to be determined with sufficient accuracy). In one embodiment, the number of quantization levels corresponds to the measuring accuracy when capturing the monitoring measured values in order to make the best possible use of the measuring accuracy. In one embodiment, the storage accuracy resulting from quantization of the monitoring measured values is not greater than the measuring accuracy.

For example, the number of quantization levels N determines the resolution of the monitoring memory values with which the monitoring takes place. In one embodiment, the quantization level is selected such that the monitoring takes place with a (still) sufficient resolution.

For example, each quantization level is assigned a specific value interval and/or value point. For example, all monitoring measured values that lie within a specific value interval are assigned to a specific monitoring memory value. In one embodiment, enough value intervals are determined to provide that the value intervals and/or value points cover the entire value range in which the monitoring measured values lie.

In one embodiment, the quantization of the monitoring measured values (e.g., the definition of the value intervals assigned to the quantization levels) takes place in dependence on the monitoring limit value. In one embodiment, the value range covered by the value intervals assigned to the quantization levels is limited by the monitoring limit value. In one embodiment, there is no quantization level with a value interval having a lower limit that is above the monitoring limit value.

In one embodiment, the value ranges assigned to the quantization levels are selected such that there is at most one value range (e.g., no value range), for which it is the case that capturing a (e.g., single) monitoring measured value (e.g., independently of any other captured monitoring measured values) in this value range (e.g., in any case and/or always and/or directly) would lead to non-compliance with the monitoring limit value (e.g., to the scan being stopped). In one embodiment, there is no quantization level for a monitoring measured value that is characterized by the fact that this monitoring measured value alone (e.g., independently of any other captured monitoring measured values) would lead to the limit value being exceeded (e.g., to the magnetic resonance scan being stopped). In one embodiment, this enables the required memory space to be kept particularly low.

In addition to quantizing the monitoring measured values, the method may also include digitizing the measurement signals for capturing (e.g., generating) the monitoring measured values during the magnetic resonance scan.

The monitoring memory values (e.g., a sequence of monitoring memory values) are stored as prefix-free code in the memory unit. In one embodiment, the sequence of monitoring memory values is ascertained from monitoring measured values captured in temporal succession. In one embodiment, the sequence of monitoring memory values includes a maximum number of monitoring memory values. In one embodiment, the sequence of monitoring memory values is ascertained from the last monitoring measured values captured in temporal succession.

A prefix-free code (e.g., often referred to as a prefix code, for short) has codewords that satisfy the property that no codeword of the code is a prefix of any other codeword. In one embodiment, a prefix-free code with variable length is used. For example, the monitoring memory values may be stored using codewords of variable length. In one embodiment, different monitoring memory values are represented by different codewords. In one embodiment, the codewords form a code that is stored in the memory unit. In one embodiment, the code represents a sequence of monitoring memory values.

In one embodiment, this may reduce the memory space required in the memory unit. For example, instead of each stored value having a fixed length of, for example, 32 bits, the monitoring memory values may be stored in the memory unit with a lower number of bits.

One possible embodiment of the method provides that monitoring the magnetic resonance scan for compliance with the limit value using the stored monitoring measured values includes stopping the magnetic resonance scan if the present limit value is exceeded. In one embodiment, stopping the scan may avoid endangering the patient (e.g., due to an excessively high SAR).

Stopping the magnetic resonance scan may, for example, include a termination (e.g., final termination) of the magnetic resonance scan. Stopping the magnetic resonance scan may, for example, include pausing (e.g., temporarily pausing) the magnetic resonance scan. Stopping may, for example, include terminating the magnetic resonance scan in accordance with a current magnetic resonance sequence and continuing the magnetic resonance scan in accordance with a modified magnetic resonance sequence.

Monitoring the magnetic resonance scan for compliance with the limit value using the stored monitoring measured values may, for example, include ascertaining an addition monitoring measured value. Ascertaining the addition monitoring measured value includes addition of the stored monitoring memory values. The magnetic resonance scan is, for example, stopped if the addition monitoring measured value exceeds the (e.g., specified) limit value.

The addition monitoring measured value may, for example, be ascertained in order to ascertain an average (e.g., a moving average) of the monitoring memory values (e.g., and thus ultimately also the monitoring measured values), for example, in accordance with equation (1):

$$MW = \frac{AW}{m} = \frac{1}{m} {\sum }_{k = 1}^{m} {SW}_{k} ,$$

where MW is the average, AW is the addition monitoring measured value, and m is the cumulative number of monitoring memory values SW. If the limit value is specified as an average, an average value MW ascertained according to equation (1) may be compared with the specified limit value. Alternatively, in such a case, the addition monitoring measured value AW may also be compared with m times the specified limit value.

In one embodiment, stopping the magnetic resonance scan also limits the memory size of the memory unit required for monitoring the magnetic resonance scan. In one embodiment, the memory size of the memory unit corresponds to the specified limit value.

In one embodiment, when adding the stored monitoring memory values, at most a number L of the most recently stored monitoring memory values is added. In one embodiment, L limits a (e.g., rolling) monitoring time window (e.g., a 10-second time window or a 6-minute time window).

In one embodiment, the monitoring measured values are captured at constant time intervals Td (e.g., every 100 ms). In one embodiment, the monitoring time window Tc may be calculated as Tc=L×Td, where Td is the time interval between two consecutive monitoring measured values.

In one embodiment, the average value according to equation (1) is formed from a maximum number L of monitoring memory values (e.g., m≤L). In the case of m<L, the average value may additionally be formed from L-m preset memory values that may, for example, have the value zero.

One possible embodiment provides that the (new) average value is calculated by adding a newly generated monitoring memory value to a previous average value and, for example, if the previous average value is formed from m<L monitoring memory values, subtracting the oldest monitoring memory value from the previous average value. In one embodiment, the previous average value is a current average value. In one embodiment, the previous average value was calculated from the most recently generated monitoring memory values. In one embodiment, the previous average value was calculated from monitoring memory values that were generated from the most recently captured monitoring measured values.

When using the prefix-free code, the memory size of the memory unit required for monitoring the magnetic resonance scan may, for example, be determined as a function of the quantization levels N of the monitoring memory values and the maximum number L of monitoring memory values to be added.

In accordance with a further embodiment of the method, the method further includes storing preset memory values in the memory unit, where the addition of the stored monitoring memory values includes an addition of K most recently stored monitoring memory values and L-K preset memory values.

The preset memory values may, for example, be understood as fictitious and/or initial monitoring memory values. In one embodiment, the preset memory values have the value zero. In one embodiment, the preset memory values facilitate the handling of the storage and/or addition of the monitoring memory values.

The preset memory values may, for example, include values from a previous magnetic resonance scan. This is, for example, possible if the period since the end of the previous magnetic resonance scan is shorter than a time window to be monitored (e.g., monitoring time window) of, for example, 6 minutes.

In one embodiment, a number M (e.g., a maximum number) of monitoring memory values is stored in the memory unit, which, in each case, were generated from the monitoring measured values that were most recently captured. In one embodiment, the maximum number L of monitoring memory values to be added is equal to the maximum number M of monitoring memory values to be stored.

However, in one embodiment, (e.g., initially) the available memory space is fully utilized (e.g., under some circumstances, more than L monitoring memory values are stored in the memory unit), and superfluous and/or unnecessary monitoring memory values are only removed from the memory unit (e.g. deleted) when required for the addition.

In one embodiment, the only monitoring memory values stored in the memory unit are those that were in each case generated from the monitoring measured values that were captured in a specified monitoring time window (e.g., in the immediate past, such as most recently).

One possible embodiment of the method provides that a number M (e.g., a maximum number) of monitoring memory values is stored in the memory unit, each of which values was generated from the monitoring measured values that were most recently captured.

For example, only the number M of monitoring memory values that were in each case generated from the monitoring measured values that were most recently captured is stored in the memory unit. In one embodiment, the number M corresponds to the maximum number of monitoring memory values required to calculate the addition monitoring measured value.

One possible embodiment of the method provides that the method further includes storing M preset memory values in the memory unit (e.g., as fictitious monitoring memory values).

In one embodiment, the preset memory values are stored before the first of the monitoring memory values is stored. The preset memory values may, for example, be stored before the start of the magnetic resonance scan, but the preset memory values may also be stored afterward.

In one embodiment, when a new monitoring memory value is stored, one of the preset memory values is removed from the memory unit (e.g., deleted) as long as at least one of the preset memory values is still stored; otherwise, the oldest monitoring memory value is removed (e.g., deleted). In one embodiment, the preset memory values are successively replaced by the monitoring memory values in the memory unit.

In one embodiment, the preset memory values supplement the monitoring memory values such that the total number of preset memory values and monitoring memory values stored in the memory unit always corresponds to a time window to be monitored (e.g., monitoring time window). In one embodiment, the monitoring memory values covering the monitoring time window are provisionally filled by the preset memory values in the memory unit (e.g., at the start of the magnetic resonance scan).

One possible embodiment of the method provides that the generation of the monitoring memory values includes normalization of the monitoring measured values (e.g., to the specified limit value). In one embodiment, this makes monitoring particularly easy to perform. In one embodiment, normalization may avoid having to adapt an assignment of codewords of the prefix-free code to (e.g., unnormalized) monitoring measured values; for example, the assignment may be kept constant independently of the specified limit value.

One possible embodiment of the method provides that the prefix-free code is a binary code, a Huffman code, or a Fibonacci code.

One possible embodiment of the method provides that the monitoring measured values describe a patient's specific absorption rate. In one embodiment, medical image data (e.g., magnetic resonance signals) are recorded during the magnetic resonance scan. The medical image data may be suitable for generating an image of the patient.

Further, a magnetic resonance apparatus is provided that is configured to execute a method as described above. The magnetic resonance apparatus may, for example, include a directional coupler (e.g., with subsequent digitization of the measured values) and/or a capacitive coupler as a unit for capturing the monitoring measured values. The magnetic resonance apparatus, for example, includes a quantization unit for generating monitoring memory values from the monitoring measured values, a memory unit for storing monitoring memory values as prefix-free code, and a monitoring unit for monitoring the magnetic resonance scan for compliance with a (e.g., specified) limit value using the stored monitoring measured values.

In one embodiment, the quantization unit, the memory unit, and the monitoring unit are part of an embedded system. The embedded system may, for example, include a digital signal processing (DSP) chip and/or an ARM system-on-chip (SoC) and/or a field programmable gate array (FPGA).

The advantages of the magnetic resonance apparatus of the present embodiments substantially correspond to the advantages of the above-described method for monitoring a magnetic resonance scan, which are explained in detail above. Features, advantages, or alternative embodiments mentioned herein may also be transferred to the other subject matter and vice versa.

Further, a computer program product is provided. The computer program product (e.g., including a non-transitory computer-readable storage medium) includes a program and may be loaded directly into a memory of a programmable system control unit and/or an embedded system of a magnetic resonance apparatus and has program means (e.g., libraries and auxiliary functions) for executing a method of the present embodiments when the computer program product is executed in the system control unit and/or the embedded system of the magnetic resonance apparatus. Herein, the computer program product may include software with a source code that still needs to be compiled and linked or only has to be interpreted, or an executable software code that only needs to be loaded into the system control unit for execution.

The computer program product may enable the method of the present embodiments to be executed quickly, identically repeatably, and robustly. The computer program product may be configured such that the computer program product may execute the method steps of the present embodiments using the system control unit. Herein, the system control unit in each case has the prerequisites for the respective method steps to be executed efficiently.

The computer program product is, for example, stored on a computer readable medium or held on a network or server from where the computer program product may be loaded into the processor of a local system control unit that may be directly connected to the magnetic resonance apparatus or may be configured as part of the magnetic resonance apparatus. Further, control information of the computer program product may be stored on an electronically readable data carrier. The control information of the electronically readable data carrier may be configured such that the control information performs a method of the present embodiments when the data carrier is used in a system control unit and/or an embedded system of a magnetic resonance apparatus.

Examples of electronically readable data carriers are DVDs, magnetic tapes, or USB sticks on which electronically readable control information (e.g., software) is stored. If this control information is read from the data carrier and stored in a system control unit and/or an embedded system of the magnetic resonance apparatus, all embodiments of the above-described methods may be performed.

Further advantages, features, and details of the present embodiments emerge from the example embodiments described below and from the drawings. Corresponding parts are provided with the same reference symbols in all figures.

### BRIEF DESCRIPTION OF THE DRAWINGS

FIG. 1 is a schematic representation of a magnetic resonance apparatus;

FIG. 2 is a diagram of a monitoring method in a first embodiment;

FIG. 3 is a diagram of a monitoring method in a second embodiment;

FIG. 4 shows an example table illustrating storage of monitoring memory values as prefix-free code in accordance with the monitoring method of the second embodiment;

FIGS. 5 and 8 show example tables illustrating the quantization of monitoring measurement data and assignment to a codeword of a prefix-free code;

FIG. 6 is a diagram of a monitoring method in a third embodiment; and

FIG. 7 shows an example table illustrating the storage of monitoring memory values as prefix-free code in accordance with the monitoring method of the third embodiment.

### DETAILED DESCRIPTION

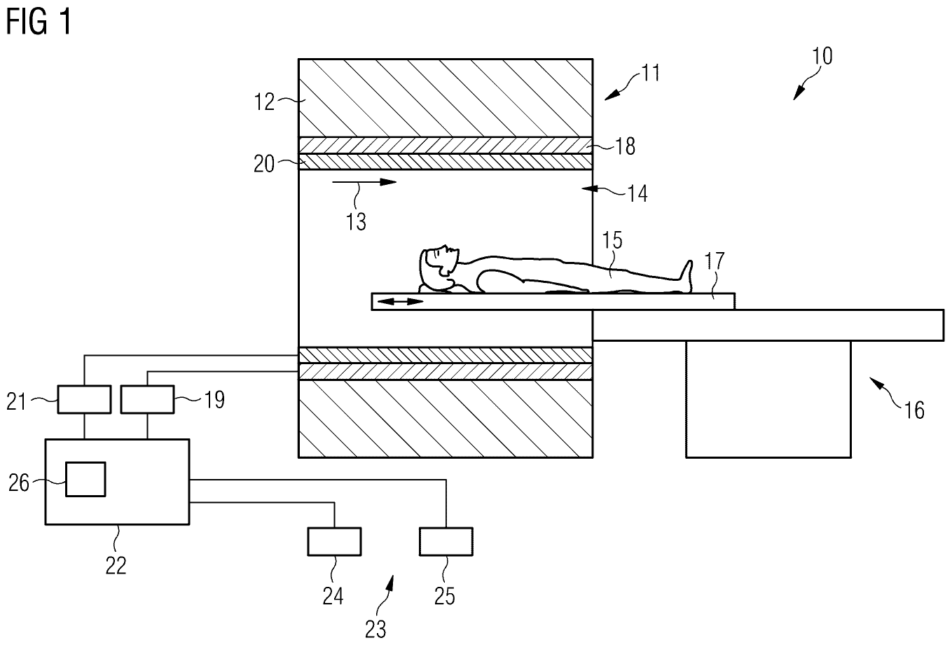

FIG. 1 is a schematic representation of a magnetic resonance apparatus 10. The magnetic resonance apparatus 10 includes a magnet unit 11 having a main magnet 12 for generating a strong and, for example, temporally constant main magnetic field 13. In addition, the magnetic resonance apparatus 10 includes a patient receiving area 14 for receiving a patient 15. In the present example embodiment, the patient receiving area 14 is cylindrical in shape and is enclosed in a circumferential direction by the magnet unit 11 in a cylindrical shape. In principle, however, a different embodiment of the patient receiving area 14 may be provided at any time. The patient 15 may be pushed into the patient receiving area 14 by a patient support apparatus 16 of the magnetic resonance apparatus 10. For this purpose, the patient support apparatus 16 has a patient table 17 configured to be movable within the patient receiving area 14.

The magnet unit 11 further has a gradient coil unit 18 for generating magnetic field gradients used for spatial encoding during imaging. The gradient coil unit 18 is controlled by a gradient control unit 19 of the magnetic resonance apparatus 10. The magnet unit 11 further includes a radio-frequency antenna unit 20 that, in the present example embodiment, is configured as a body coil permanently integrated into the magnetic resonance apparatus 10.

The radio-frequency antenna unit 20 is controlled by a radio-frequency antenna control unit 21 of the magnetic resonance apparatus 10 and radiates radio-frequency pulses into an examination area that is substantially formed by a patient receiving area 14 of the magnetic resonance apparatus 10. This causes the main magnetic field 13 generated by the main magnet 12 to excite atomic nuclei. Magnetic resonance signals are generated by relaxation of the excited atomic nuclei. The radio-frequency antenna unit 20 is configured to receive the magnetic resonance signals.

The magnetic resonance apparatus 10 has a system control unit 22 for controlling the main magnet 12, the gradient control unit 19, and for controlling the radio-frequency antenna control unit 21. The system control unit 22 controls the magnetic resonance apparatus 10 centrally, such as, for example, performing a predetermined imaging gradient echo sequence. In addition, the system control unit 22 includes an evaluation unit, not shown in detail, for evaluating the magnetic resonance signals that are captured during the magnetic resonance examination. Further, the magnetic resonance apparatus 10 includes a user interface 23 connected to the system control unit 22. Control information such as imaging parameters and reconstructed magnetic resonance images may be displayed on a display unit 24 (e.g., on at least one monitor) of the user interface 23 for a medical operator. The user interface 23 also has an input unit 25 by which information and/or parameters may be entered by the medical operator during a scanning process.

The irradiated RF pulses are partially absorbed by tissue of the patient. The radio-frequency energy per unit of time and per kilogram of body weight may be referred to as the specific absorption rate (SAR). Absorption of the RF energy may lead to heating of the body tissue of the patient 15. Energy absorption is an important parameter for defining safety limits. If the local concentration of RF energy is inadmissibly high, RF burns may occur (local SAR). If the RF energy is evenly distributed over the entire body, the strain on the thermoregulation or the cardiovascular system of the patient 15 is decisive (e.g., whole-body SAR).

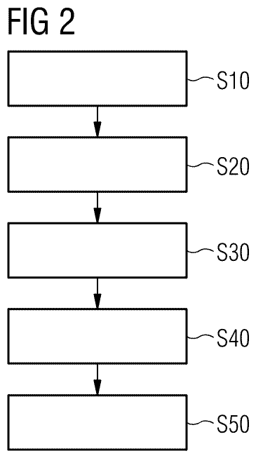

FIG. 2 is a representation of a computer-implemented method for monitoring a magnetic resonance scan. Such monitoring may, for example, include monitoring SAR exposure of a patient. In S10, a magnetic resonance scan is started. During the magnetic resonance scan, monitoring measured values MW are captured. In S30, monitoring memory values are generated by quantizing the monitoring measured values. In S40, the monitoring memory values SW are stored as prefix-free code in a memory unit 26 of the magnetic resonance apparatus 10. In S50, the magnetic resonance scan is monitored for compliance with a (specified) limit value using the stored monitoring measured values.

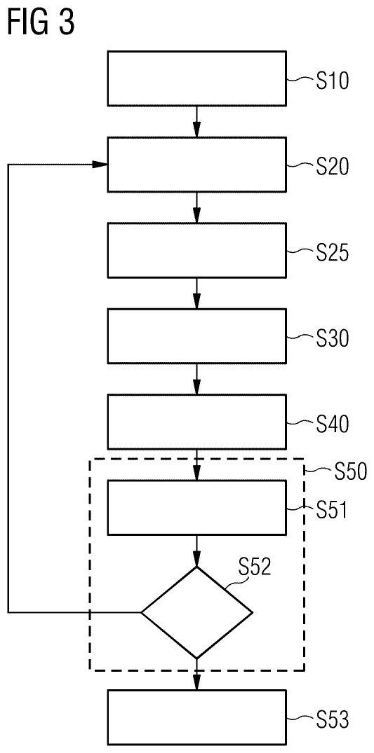

FIG. 3 is a representation of an extended variant of a computer-implemented method for monitoring a magnetic resonance scan. After capturing the monitoring measured values MW in S20, the monitoring measured values are normalized in S25.

In one embodiment, monitoring the magnetic resonance scan for compliance with the limit value in S50 includes ascertaining an addition monitoring measured value in S51. Ascertaining the addition monitoring measured value includes the addition of the stored monitoring memory values, where at most the L of the most recently stored monitoring memory values is added. In S52, the addition monitoring measured value is used to ascertain whether the limit value is exceeded. If the limit value is exceeded, the magnetic resonance scan is stopped in S53. If the limit value is not exceeded, the magnetic resonance scan is continued, and further monitoring measured values are captured and evaluated according to S20, S25, S30, S40, S50.

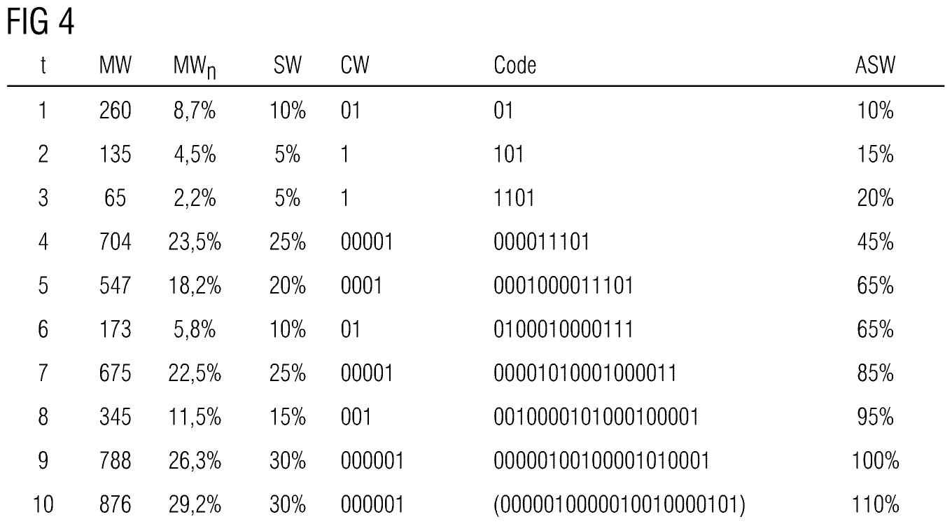

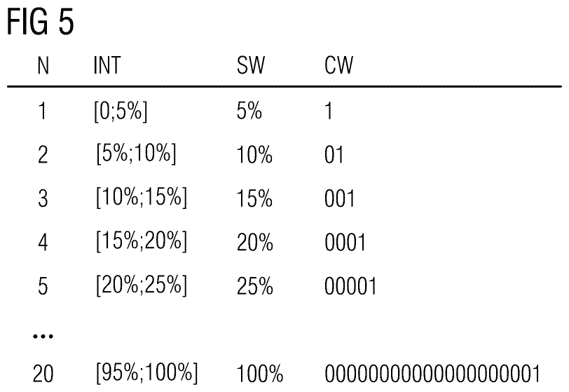

Possible aspects of the method of the present embodiments will be explained in more detail with reference to a specific example in accordance with FIG. 4 and FIG. 5. In accordance with S20, monitoring measured values MW are captured at various time points t. In one embodiment, the time points t have constant time intervals. In this example, the time points t are represented as dimensionless numbers 1, 2, . . . , 10. Herein, these may, for example, be seconds.

Likewise, the monitoring measured values MW are shown here by way of example as dimensionless numbers 260, 135, . . . , 876. The monitoring measured values MW may represent physical measured values, such as, for example, a measured power.

In this example, the limit value specified is that the sum of the monitoring measured values MW is not to exceed 3000 in a rolling time window of five time units. Such a limit value is equivalent to the average value of the monitoring measured values not exceeding 3000/5=600 in the rolling time window of five time units.

In S25, the monitoring measured value MW is normalized to the limit value GW=3000, and hence, the normalized monitoring measured value MWn is generated; herein, the monitoring measured value MW is, for example, divided by the limit value GW. In S30, the normalized monitoring measured values MWn are quantized into, for example, twenty levels; herein, the quantization resolution is 5%. This is illustrated in FIG. 5. Herein, each quantization level N is assigned, for example, a value interval INT with a width 5% (e.g., the quantization resolution is equal to the interval width). In one embodiment, quantization is carried out in equal steps (e.g., the width of the value intervals INT is always the same for each quantization level N).

Each quantization level N is assigned a monitoring memory value SW and an associated codeword CW (sometimes also referred to as a code symbol). In one embodiment, the monitoring memory value SW is in each case the upper limit of the respective value interval INT. As a result, the normalized monitoring measured value MWn is always rounded up (e.g., conservatively) during quantization in S30. In one embodiment, this makes monitoring of the magnetic resonance scan particularly reliable.

Instead of rounding up, it is possible to round down (e.g., truncate) and add the remainder to the next measured value. Thus, although the temporal assignment may possibly not be exactly correct, the sum is correct apart from a quantization interval.

The codewords CW have the property that the codewords CW are codewords of a prefix-free code: a prefix-free code designates a code that satisfies the Fano condition according to which no codeword of the code is a prefix of another codeword. In one embodiment, hence, the codewords of a prefix-free code may be simply strung together; nevertheless, the code may still be broken down or decoded into its codewords.

This example entails a binary code in which the elements of the code symbols only consist of “0” or “1”. The length of each codeword CW is equal to its quantization level N. Each codeword CW consists of N−1 zeros and a one at the end. However, it is also conceivable to use another prefix-free code, such as, for example, a Huffman code or a Fibonacci code.

If the assignment table from FIG. 5 is now applied to the example in FIG. 4, the monitoring memory value SW=10% and the codeword CW=01 are assigned to the monitoring measured value MWₙ=8.7% captured and normalized at time point t=1. The resulting code initially only includes the first codeword (e.g., 01). The addition monitoring measured value ASW ascertained in S51 results from the addition of the L=5 most recently stored monitoring memory values SW. At time point t=1, this only affects the first stored monitoring memory values SW=10%.

In the same way, the monitoring measured value MW=135 captured at time point t=2 in S20 or the corresponding monitoring measured value MWₙ=135/3000=4.5% normalized in S25 is assigned codeword CW=1 after quantization in S30. The monitoring memory values of the time points t=1 and t=2 are then stored as code with 101 (e.g., a sequence of the respective codewords in S40). The addition monitoring measured value ASW at time point t=2 results from the addition of the monitoring memory values SW 10% (for t=1) and 5% (for t=2) (e.g., a total of 15%).

The monitoring in S50 shows for both time points t=1 and t=2 that the respective addition monitoring measured values ASW 10% or 15% do not exceed the limit value (e.g., normalized limit value) of 100%, so that, for example, the magnetic resonance scan is not stopped. Similarly, the limit value is also not exceeded for the following time points up to t=9. The limit value is then exceeded at time point t=10 because ASW=110%>100%. However, the code describing this no longer needs to be stored since the magnetic resonance scan is stopped in S53 when the limit value is exceeded, and hence, there is no need for the code to be saved. Therefore, the code is given in parentheses.

Since only the L=5 most recently stored monitoring memory values SW are ever used for the addition in S51, correspondingly older codewords CW may also be removed again from the code from time point t=6. In one embodiment, a number (e.g., a maximum number, M) of monitoring memory values is stored in the memory unit, each of which was generated from the monitoring measured values that were most recently captured. In one embodiment, M=L.

In one embodiment, the prefix-free code is a variable-length code: the code may have a different length depending on the time point t. For example, at time point t=1, the length is 2; at time point t=2, the length is 3; at time point t=3, the length is 4; at time point t=4, the length is 9, etc.

In one embodiment, the length of the code corresponds to the addition monitoring measured value ASW at the respective time point. The relationship here is code length=addition monitoring measured value ASW/quantization resolution. Since the addition monitoring measured value ASW may be 100% at most, because otherwise, the scan would be stopped, the memory size of the memory unit may be limited to 20 bits in this example.

Conventionally, each monitoring memory value would typically be stored with a 32-bit float, which would require a memory of 5×32 bits=160 bits for five monitoring memory values. For this exemplary demonstration, this would result in a reduction factor of 8. However, in real applications, this reduction factor may be significantly larger, since usually a much larger number of time points is to be taken into account. Monitoring a six-minute rolling time window with a time interval of 100 milliseconds results in 3600 values. Conventionally, this provides a memory requirement of 3600×32=115200 bits.

With a practically useful quantization resolution of 0.5% or the 200 quantization levels N required for this, the proposed method has of a memory requirement of 200 bits and thus a reduction factor of 576.

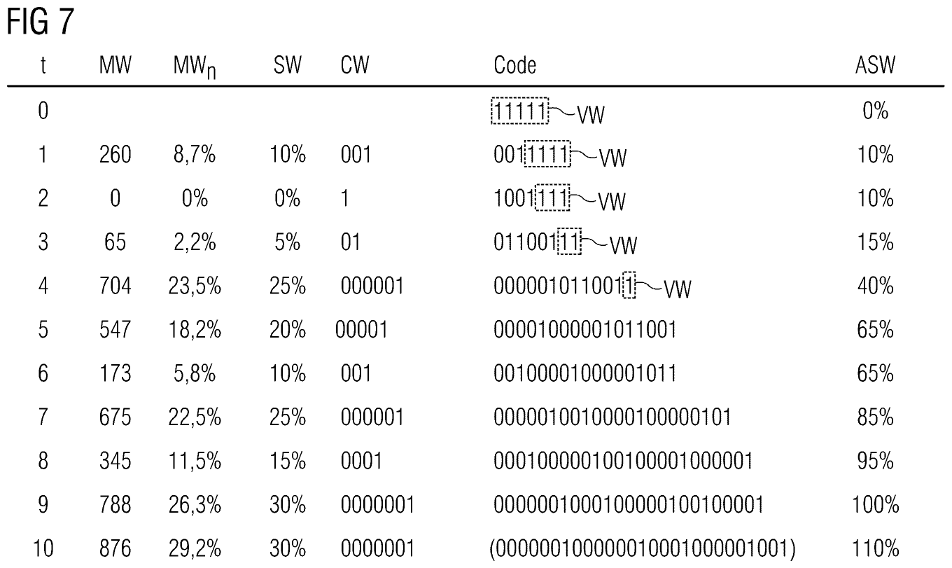

FIG. 7 represents a further possible method. Here, preset memory values VW are stored in the memory unit 26 in S15. In one embodiment, in each case, one of the preset memory values VW is assigned to each time period of a monitoring window. In one embodiment, the preset memory values VW have the value zero in each case. In one embodiment, the preset memory values VW function as provisional monitoring memory values SW.

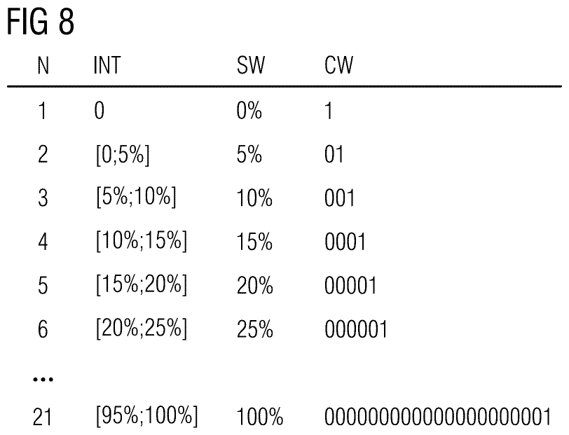

In accordance with the table in FIG. 8, for example, the codeword CW 1 is assigned to a monitoring memory value SW of zero. In accordance with the example in FIG. 7, (as in the example in FIG. 4 and FIG. 5), the monitoring window includes five time periods. Accordingly, at time point t=0, the code consists of five codewords CW=1 (e.g., 11111).

At time point t=1, the codeword CW=001 is then ascertained for the captured monitoring measured value MW=260 in accordance with the above-described method. To store the code, one of the codewords CW=1 of the preset memory value VW is then replaced by this codeword CW=001.

At time point t=2, a monitoring measured value MW=0 is captured. This may, for example, be the case if no RF pulse is transmitted by the magnetic resonance apparatus 10 at this time point (e.g., the patient 15 is not exposed to RF power). Accordingly, a corresponding preset memory value is then stored by the codeword CW=1 and, at the same time, a preset memory value VW with the codeword CW=1 is removed, so that the code now only includes three preset memory values VW that are in each case represented by a codeword CW=1.

In one embodiment, the preset memory values VW may, for example, simplify the addition of the memory values in S51, because the number of summands is always the same (e.g., also at the beginning).

As already explained, monitoring a six-minute time window with a time interval of 100 milliseconds results in 3600 values, for which a memory requirement of 115200 bits is conventionally necessary.

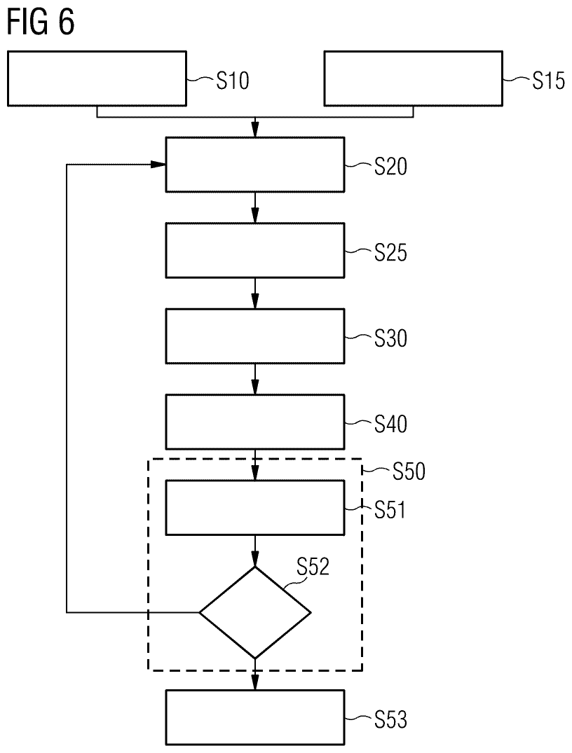

Likewise, it has already been explained that a quantization resolution of 0.5% or the 200 quantization levels N required for this results in a memory requirement of 200 bits; further, in accordance with the variant in FIG. 6, when using the preset memory values VW, a further bit of memory space is required for each time period. This results in a total memory space of 200+3600=3800 bits. This represents a reduction by a factor of about 30 compared to conventional storage.

When applied to SAR monitoring, the method of the present embodiments makes use of the following properties, for example: SAR values have an upper limit and a lower limit. A SAR value may never be lower than zero, and a SAR value is also not to be greater than the specified limit value. The limit value may, for example, be normalized to one. The measuring accuracy of the monitoring measured values is limited in practice. Hence, it is also sufficient to store the monitoring measured values with a certain accuracy (e.g., 0.5%, corresponding to 200 quantization levels). In the event (e.g., which is unlikely in practice) that the specified SAR limit value is exceeded, the magnetic resonance scan (e.g., and thus also the output of RF power) may be stopped. This may reliably prevent the SAR limit value from being greatly exceeded.

These properties make it possible to divide the SAR contributions into discrete parts within a monitoring time window (e.g., a rolling monitoring time window). These may be stored with the aid of a prefix-free code.

Finally, reference is made once again to the fact that the methods described above and the magnetic resonance apparatus depicted are example embodiments only and may be modified by the person skilled in the art in a wide variety of ways without departing from the scope of the invention. Further, the use of the indefinite articles “a” or “an” does not exclude the possibility that the features in question may also be present on a multiple basis. Likewise, the term “unit” does not exclude the possibility that the components in question consist of a plurality of subcomponents that may also be spatially distributed. Independent of the grammatical term usage, individuals with male, female, or other gender identities are included within the term.

The elements and features recited in the appended claims may be combined in different ways to produce new claims that likewise fall within the scope of the present invention. Thus, whereas the dependent claims appended below depend from only a single independent or dependent claim, it is to be understood that these dependent claims may, alternatively, be made to depend in the alternative from any preceding or following claim, whether independent or dependent. Such new combinations are to be understood as forming a part of the present specification.

While the present invention has been described above by reference to various embodiments, it should be understood that many changes and modifications can be made to the described embodiments. It is therefore intended that the foregoing description be regarded as illustrative rather than limiting, and that it be understood that all equivalents and/or combinations of embodiments are intended to be included in this description.

1. A method for monitoring a magnetic resonance scan, the method being computer-implemented and comprising:
providing monitoring measured values captured during the magnetic resonance scan;
generating monitoring memory values, the generating of the monitoring memory values comprising quantizing the monitoring measured values;
storing the monitoring memory values as prefix-free code in a memory unit; and
monitoring the magnetic resonance scan for compliance with a limit value using the stored monitoring memory values.

2. The method of claim 1, wherein the monitoring memory values are stored as prefix-free code of variable length.

3. The method of claim 1, wherein monitoring the magnetic resonance scan for compliance with the limit value using the stored monitoring measured values comprises:
stopping the magnetic resonance scan when the limit value is exceeded.

4. The method of claim 1, wherein monitoring the magnetic resonance scan for compliance with the limit value using the stored monitoring measured values comprises:
ascertaining an addition monitoring measured value,
wherein ascertaining the addition monitoring measured value comprises:
adding the stored monitoring memory values, wherein at most a number L of most recently stored monitoring memory values are added; and
stopping the magnetic resonance scan when the limit value is exceeded, in particular if the addition monitoring measured value exceeds the limit value.

5. The method of claim 4, wherein stopping the magnetic resonance scan when the limit value is exceeded comprises stopping the magnetic resonance scan when the addition monitoring measured value exceeds the limit value.

6. The method as claimed in claim 4, further comprising:
storing preset memory values in the memory unit,
wherein adding the stored monitoring memory values comprises adding a number K of most recently stored monitoring memory values and a number L-K of stored preset memory values.

7. The method of claim 1, wherein at most a number M of monitoring memory values generated in each case from the monitoring measured values that were most recently captured is stored in the memory unit.

8. The method of claim 7, further comprising storing M preset memory values in the memory unit,
wherein:
when a new monitoring memory value is stored, one of the preset memory values is removed as long as at least one of the preset memory values is still stored; and
otherwise, the oldest monitoring memory value is removed.

9. The method of claim 1, wherein the monitoring measured values are monitoring measured values captured at constant time intervals.

10. The method of claim 1, wherein the quantizing of the monitoring measured values is carried out in N quantization levels,
wherein a value interval is assigned to each of the N quantization levels, and
wherein all monitoring measured values that lie within a respective value interval are assigned to a defined monitoring memory value.

11. The method of claim 1, wherein generating the monitoring memory values comprises normalizing the monitoring measured values, in particular to the specified limit value.

12. The method of claim 11, wherein normalizing the monitoring measured values comprises normalizing the monitoring measured values to the specified limit value.

13. The method of claim 1, wherein the prefix-free code is a binary code, a Huffman code, or a Fibonacci code.

14. The method of claim 1, wherein the monitoring measured values describe a specific absorption rate of a patient.

15. A magnetic resonance apparatus comprising:
a processor configured to monitor a magnetic resonance scan, the processor being configured to monitor the magnetic resonance scan comprising the processor being configured to:
provide monitoring measured values captured during the magnetic resonance scan;
generate monitoring memory values, the generation of the monitoring memory values comprising quantization of the monitoring measured values;
store the monitoring memory values as prefix-free code in a memory unit; and
monitor the magnetic resonance scan for compliance with a limit value using the stored monitoring measured values.

16. In a non-transitory computer-readable storage medium that stores instructions executable by one or more processors to monitor a magnetic resonance scan, instructions comprising:
providing monitoring measured values captured during the magnetic resonance scan;
generating monitoring memory values, the generating of the monitoring memory values comprising quantizing the monitoring measured values;
storing the monitoring memory values as prefix-free code in a memory unit; and
monitoring the magnetic resonance scan for compliance with a limit value using the stored monitoring measured values.
